(19) United States
(12) Patent Application Publication
(10) Pub. No.: US 2003/0222799 A1
(43) Pub. Date: Dec. 4, 2003

(54) Computer keyboard with storage area

(76) Inventor: Alan K. Uke, Del Mar, CA (US)

Correspondence Address: FOLEY & LARDNER, P.O. BOX 80278, SAN DIEGO, CA, 92138-0278, US

(21) Appl. No.: 10/243,998

(22) Filed: Sep. 12, 2002

Related U.S. Application Data
(63) Continuation-in-part of application No. 10/156,736, filed on May 29, 2002.

(51) Int. Cl. H03M 11/00; H03K 17/94; B41J 29/12

(52) U.S. Cl. 341/22; 400/717

(57) ABSTRACT

A computer keyboard having a plurality of keys located at an upper side of the keyboard. The housing also has a storage area at another side of the keyboard suitable for storing computer readable media and/or paperwork.

### RELATED APPLICATION

This application is a continuation-in-part of Alan Uke, U.S. application Ser. No. 10/156,736, filed May 29, 2002, which is incorporated by reference herein in its entirety, including all drawings.

### FIELD OF THE INVENTION

The present invention relates to computer keyboards, and more specifically to computer keyboards having a storage area for storing objects.

### BACKGROUND

Computer users often have volumes of computer readable secondary storage devices or media, such optical and magnetic disks, that store executable programs, graphics files, backup files, etc. Besides these items, computer users also have numerous manuals and other paper work associated with software. Despite the availability of file cabinets and storage boxes, many users unfortunately misplace or lose the computer readable medium and computer related paperwork. In many instances, computer users need to access the contents of such computer readable medium and computer related paperwork. For example, executable programs, such as that for an operating system, often need to be reinstalled. If a compute user has misplaced the computer readable medium or paperwork associated with the program, the user is typically required to purchase a new version of the program for installation on the user's computer. In light of this problem, a need exists for an easily recollected location where computer users can store critical computer readable medium and/or computer related paperwork.

### SUMMARY OF THE INVENTION

The present invention provides a convenient means for retaining computer readable media and/or paperwork in association with a computer by providing a computer keyboard that includes a storage area or areas suitable for storing computer readable secondary storage medium and/or computer related paperwork. Typically the keyboard includes a housing, with the keys at the upper side of the housing. The storage area is generally located on the underside of the keyboard, and is accessible from the underside or from one of the other sides, depending on the particular configuration of the storage area and/or closure or cover for the storage area. The size of the storage area can also vary, allowing storage of various quantities of materials. Use of these storage areas thus provides a safe storage location, in close physical association with the computer to which the stored material most likely relates, but a location that is also unlikely to be accidentally disturbed or to have the storage media or paperwork mixed with unrelated storage media and paperwork or other materials. Such keyboard storage areas are particularly advantageous for storing the critical disks (or other secondary storage media) for operation of the associated computer, as distinguished from general storage or filing of disks or other storage media items. Such critical disks can include, for example, disks containing the operating system, utilities, and/or most important programs (such as word processor, communications, image editing, and other software of particular importance to a particular user). The number of disks and/or other storage media items will typically be 10 or less, i.e., 1, 2, 3, 4, 5, 6, 7, 8, 9, or 10. When used in this way, the storage area serves as convenient central location for locating the software essential for recovering computer function in the event a critical program or operating system file is corrupted or one or more files otherwise need to be replaced or installed.

As indicated, the storage area (and the remainder of the keyboard) can be configured in various ways. For example, the space or volume for the storage area can be created by the sidewalls (i.e., transverse walls) of the keyboard with or without a cover enclosing the storage volume of the storage area, or by having legs on the bottom of the keyboard to create a desired elevation, thereby making space for a storage area of corresponding depth. Thus, the walls or legs can be extended to create a deeper or shallower storage area as desired. For any configuration of keyboard and storage area, a support of some type is provided to hold stored materials from dropping down from the storage area. In most cases, such support is provided by a structure under a storage area, or forming the bottom of a storage area. Examples of such supports include covers, bands (which may for example be rigid, semi-rigid, or flexible) straps, lower portions of storage receptacles or other containers, and the like. Alternatively, a support may hold the stored material directly, without forming a support under the storage area. Examples of such direct supports include disk holding hubs or posts, e.g., for compact disks. Such hubs or posts (or similar structures for other storage media) can utilize friction to hold the media and/or can utilize a center retainer that holds a disk(s) in place at the center, e.g., a ring or disk with an outer diameter slightly larger than the central hole of a type of disk that is to be held.

The storage area can also be configured in various ways. In certain embodiments, the storage area is a space or volume defined by surfaces at the lower side of the keyboard or by the keyboard and the surface on which the keyboard rests (for example, when the volume for storage is created by legs on the lower side of the keyboard), where the volume may be covered or uncovered on the access side. The storage area may be fully enclosed, (e.g., a cavity with a cover or a bin with or without a cover, where the bin abuts the lower surface of the keyboard such that the cover or the underside of the keyboard completes the enclosure. The storage area may be less than fully enclosed, such that a volume is provided for storage, but items stored therein are partially exposed. For example, the storage area may include one or more U-shaped straps (fixed, removable, or moveable, e.g. hinged at one side) and/or a cup (e.g., shallow rectangular cavity) that retain stored items. Thus, the structure that holds items in the storage area need not be solid on all sides (including a cover), but can be constructed in various ways to provide a lower support and/or protection for stored items. As indicated, such support/protection can be provided by structures that have openings, e.g., of sufficient size to allow at least some stored materials to be identified without removal from the storage area. A storage area can be an area separated from the interior of the keyboard by a wall, or can be a portion of the interior, e.g., below the keys and the switch circuit board or other switch construct.

A storage area can be shaped and/or sized for storage of particular types of items. For example, a storage area can be sized and/or shaped to hold up to a pre-selected number of CDs, DVDs, floppy disks, 3.5 inch floppy disks, or other format storage media. The shape of a storage area can be selected to generally match the medium to be stored (e.g., circular and at least slightly larger than a circular disk to be stored, or can be any convenient shape that is also sufficiently large to accommodate the desired medium, e.g., rectangular with a minimum dimension at least slightly larger than the medium that is to be stored. For example, for CDs a storage area will generally accommodate disks of approximately 120 mm diameter. The depth or thickness selected for a storage area will depend on the medium to be stored and the number of disks or other media that are intended to be stored. In some embodiments, an area will be sized to hold one or a few storage media items, e.g., 1, 2, 3, 4, or 5 such items. For a particular type of storage media item, there should be an available depth that is at least as great as the number of items times the thickness of each item (e.g., approximately 1-1.5 mm for CDs, approximately 3.5 mm for 3.5 inch floppy disks). For providing protection to storage media and/or making removal easier and/or other advantages, it can be beneficial to provide additional depth, e.g., to allow media to be spaced somewhat from each other. In addition, the depth of a storage area can be designed to accommodate protective structures, such as CD cases, for the stored items. Exemplary CD cases are 5-10 mm thick, e.g., approximately 7 mm. Exemplary storage areas will be thus, for example, be 1-50 mm in thickness, 2-30 mm, 5-30 mm, 10-40 mm, 10-50 mm, 20-30 mm, 20-40 mm, 20-50 mm, 30-40 mm, or 30-50 mm.

Storage of secondary media and/or paperwork or other materials may be directly in the storage area or in a storage receptacle that is attached in the storage area. For example, a rigid or semi-rigid box or drawer or a rigid, semi-rigid, or flexible pocket or folder or other storage receptacle can be attached in the storage area, where the box, drawer, or pocket can be slid and/or detached and/or unfolded from the body of the keyboard. A detachable storage receptacle can be held or attached in various ways; e.g., held or attached using one or more clips, latches, straps (e.g., elastic), hook and loop fastener (e.g., VELCRO®); releasable adhesive, pockets, and/or bands, or by being contained within a compartment such as in a pocket, bin, or drawer.

Access may be from the underside of the keyboard and/or from one or more of the other sides (e.g., a sliding drawer(s) that extends out a transverse side(s) when opened or a slot with or without a door or cover where the opening is on one of the transverse sides. When the space is covered, the cover may, for example, be rigid, semi-rigid, flexible, or soft. A cover may be clipped, hinged, held by a fastener(s), e.g., hook and loop fastener such as VELCRO® fastener, or by a releasable adhesive.

As used herein, the term “storage area” refers to a physical location of a keyboard where a storage volume is at least partially defined by keyboard structure. Materials may be stored directly in that storage volume, or may be in one or more storage receptacles that are located in the storage area.

“Storage receptacle” refers to a structure adapted to fit in a storage area and contain paperwork, storage media, or other materials. A storage receptacle can be moveable, e.g., slidable or swingable, removable, or attachable to a keyboard. Typically, a storage receptacle will be made of plastic (e.g., molded plastic), metal, and/or cloth. Such receptacles may be in various forms, e.g., drawers, tubs or bins, sleeves, straps, and the like.

As used in connection with a computer keyboard, the term “housing” refers to a structure that at least partially contains components of the keyboard. Generally the housing will be made of rigid or semi-rigid material, e.g., molded thermoset plastic. Typically, keys will be mounted in or protrude through an upper side or surface of a keyboard housing and/or switch and other circuit components will be located inside the housing.

In a related aspect, the invention also provides a computer system that includes at least one central processing unit (CPU) and a computer keyboard that has at least one storage area as described herein. Typically the CPU(s) will be in a case or housing, which will usually also include other components typical for personal and mini computers, e.g., disk drives, modem, video card, audio card, power supply, and the like. The computer will typically also include a display device, such as a CRT, LCD, or other computer monitor. The storage area can contain at least one secondary storage medium item, e.g., 1, 2, 3, 4, 5, or even more such items, and/or papers, books or booklets, and the like.

In another related aspect, the invention provides a method for storing secondary storage media with a computer that involves placing or storing one or more secondary storage media items in a storage area in a computer keyboard as described herein, where the keyboard is functionally part of the computer, i.e., signals resulting from depressing keys on the keyboard are received and processed by another component(s) of the computer.

Additional embodiments, advantages and features associated with the present invention will be apparent to those skilled in the art from the following detailed description and from the claims. As will be realized, the invention is capable of other and different embodiments, and its several details are capable of modification in various obvious aspects, all without departing from the invention. Accordingly, the drawings and the description are to be regarded as illustrative in nature, and not limitative.

### BRIEF DESCRIPTION OF THE DRAWINGS

FIG. 1 is perspective view of an upper side of a computer keyboard in accordance with one embodiment of the present invention.

FIG. 2 is perspective view of a bottom side of the computer keyboard illustrated in FIG. 1, where a storage area of the computer keyboard is closed.

FIG. 3 is perspective view of the bottom side of the computer keyboard illustrated in FIG. 1, where the storage area of the keyboard is open.

FIG. 4 is an exploded view of the computer keyboard illustrated in FIG. 1.

FIG. 5 is a partial cross-sectional view of the computer keyboard illustrated in FIG. 1, taken along the line 5-5 in FIG. 2 and illustrating a cover of the computer keyboard in a closed position.

FIG. 6 is a partial cross-sectional view of the computer keyboard illustrated in FIG. 1, taken along the line 6-6 in FIG. 1 and illustrating the cover of the computer keyboard in an open position.

FIG. 7 is a perspective view of a bottom side of a second embodiment of a computer keyboard in accordance with the present invention, where a storage area of the computer keyboard is closed by a cover.

FIG. 8 is a perspective view of a bottom side of the computer keyboard illustrated in FIG. 7, where the cover is open to expose the storage area of the computer keyboard.

FIG. 9 is a perspective view of a bottom side of a third embodiment of a computer keyboard in accordance with the present invention, where two storage areas of the computer keyboard are closed by covers.

FIG. 10 is a perspective view of a bottom side of the computer keyboard illustrated in FIG. 9, where the covers are open to expose the storage areas of the computer keyboard.

FIG. 11 is a perspective view of a bottom side of a fourth embodiment of a computer keyboard in accordance with the present invention, where a storage area of the computer keyboard is closed by a cover.

FIG. 12 is a perspective view of a bottom side of the computer keyboard illustrated in FIG. 11, where the cover is open to expose the storage area of the computer keyboard.

FIG. 13 is a perspective view of a bottom side of a fifth embodiment of a computer keyboard in accordance with the present invention, where a storage area of the computer keyboard is closed by a cover.

FIG. 14 is a perspective view of a bottom side of the computer keyboard illustrated in FIG. 13, where the cover is open to expose the storage area of the computer keyboard.

FIG. 15 is a perspective view of a bottom side of a sixth embodiment of a computer keyboard in accordance with the present invention, where a first storage area of the computer keyboard is closed by a cover and a second storage area of the computer keyboard is exposed.

FIG. 16 is a perspective view of a bottom side of the computer keyboard illustrated in FIG. 15, where the cover is open to expose the first storage area of the computer keyboard.

FIG. 17 is a perspective view of a bottom side of a seventh embodiment of a computer keyboard in accordance with the present invention, where a storage area of the computer keyboard includes a receptacle therein.

FIG. 18 is a perspective view of a bottom side of the computer keyboard illustrated in FIG. 17, where the receptacle has been removed from the storage area.

FIG. 19 is a perspective view of an alternative embodiment of a receptacle for use with the computer keyboard illustrated in FIGS. 17 and 18.

### DETAILED DESCRIPTION OF THE PREFERRED EMBODIMENTS

As described in the Summary above, a large number of embodiments of computer keyboards with storage areas can be designed and constructed. Included in the various types of storage areas, are configurations with open, partially open, and closed storage areas. In addition, moveable or removable storage receptacles can be included, including slidable drawers, removable sleeves, and the like. Further, a variety of different types of covers can be used to close and opening to a storage area. In many cases, the storage area or areas in a keyboard are accessible from the underside of the keyboard, but storage areas can also be configured for access in other ways, e.g., access from a side (including any of the front, back, and lateral sides) into a pocket opening to the side, or from above, e.g., access from above into an open top slidable drawer that slides out one of the sides.

While in many embodiments the keyboard is separate from other components of the computer, storage areas as described herein can also be designed and constructed in laptop, notebook, and other such portable computers. In these cases, the capability to store important software or other materials can be of even greater importance as such computers are often used away from the “home” geographic location where the materials would otherwise be stored. For such computers storage areas will usually be constructed on the bottom of the computer, though other locations can also be used, such as a drawer or tray in the side of computer (e.g., in a similar location to those commonly used for installation of CD and other disk drives). While storage areas for such portable computers can be constructed in many different ways as described for separate keyboards, for portable computer applications the storage area may advantageously be designed to accommodate one more types of storage media appropriate for the particular computer (e.g., CDs, DVD, solid state memory modules or cards). In most cases, the storage area will be relatively shallow, e.g., less than 10 mm, less than 7 mm, or less than 5 mm in depth. Also in most cases, the storage area will be fully covered, e.g., the storage area will have a moveable or removable cover, or the storage area will be in the form of a drawer that slides out for access. It can also be advantageous for portable applications that the disks or other media is restrained from movement relative to the computer to protect against damage to the storage media (and/or to the computer). Such restraint can, for example be provided by pressure holding the items in place, posts that provide friction or clamp retaining ability, as well as other techniques).

FIGS. 1-19 illustrate embodiments of computer keyboards 100, 200, 300, 400, 500, 600, 700 in accordance with exemplary embodiments of the present invention. As described below, the computer keyboards 100, 200, 200, 400, 500, 600, 700 each include one or more storage areas in which a user of the keyboard can store objects, such computer readable medium 50 and computer related document 60 to lessen the chance that the user will misplace the objects. Because the computer keyboards 100, 200, 300, 400, 500, 600, 700 are functionally similar and share a number of similar parts, in the following description like numbered parts of the computer keyboards 100, 200, 300, 400, 500, 600, 700 are referred to by like numbers, increased by 100's and/or letters (a, b, c).

As illustrated in FIGS. 1-6, the computer keyboard 100 is an input device for a computer (not illustrated) and has a set of alphabetic, numeric, punctuation, symbol and/or control keys 102. When a user presses one of the keys 102, a signal is sent to the computer, which responds to the signal by displaying a character on screen or taking some other action. Hence, the computer keyboard 100 is hardwired or wirelessly connected to a computer, which is a device that follows instructions to alter data in a desirable way and to perform at least some operations without human intervention. Examples of computers to which the computer keyboard 100 can be connected include personal computers, laptop computers, personal digital assistants, etc. In a preferred embodiment, the computer keyboard 100 does not have processing capabilities (other than interpreting and generating signals in response to keyboard strokes) and is physically separate from a computer to which the computer keyboard is connected, i.e., it is not integral with a computer, similar to most conventional computer keyboards that are configured for use with conventional personal computers.

The illustrated computer keyboard 100 includes a housing 103 having an upper portion 104 and a lower portion 105. In alternative embodiments, the housing 103 is defined by more or less portions and by differently divided portions. For example, the housing 103 may have lateral halves. The housing 103 is preferably molded, but may be cast, machined, stamped, etc. In the illustrated embodiment, the upper portion 104 of the housing 103 includes an upper side 106 that typically faces a user of the computer keyboard 100 during operation of the computer keyboard 100. Likewise, the bottom portion 105 of the housing 103 has an underside, lower side or bottom side 107 that is located opposite from the upper side 106 and is the surface upon which the computer keyboard 100 typically rests when a user strikes the keys 102. In one embodiment where the computer keyboard 100 is a keyboard for a personal computer, the keys 102 are arranged in the conventional Qwerty or Dvorak format. In another embodiment, the keys 102 are arranged in a four by three grid. The keys 102 have illustrations thereon, such as alphanumeric characters. The keys 102 are of a conventional format, preferably each having a non-resilient (stiff) strike portion and a protrusion that retains the key in the computer keyboard 100 as described below.

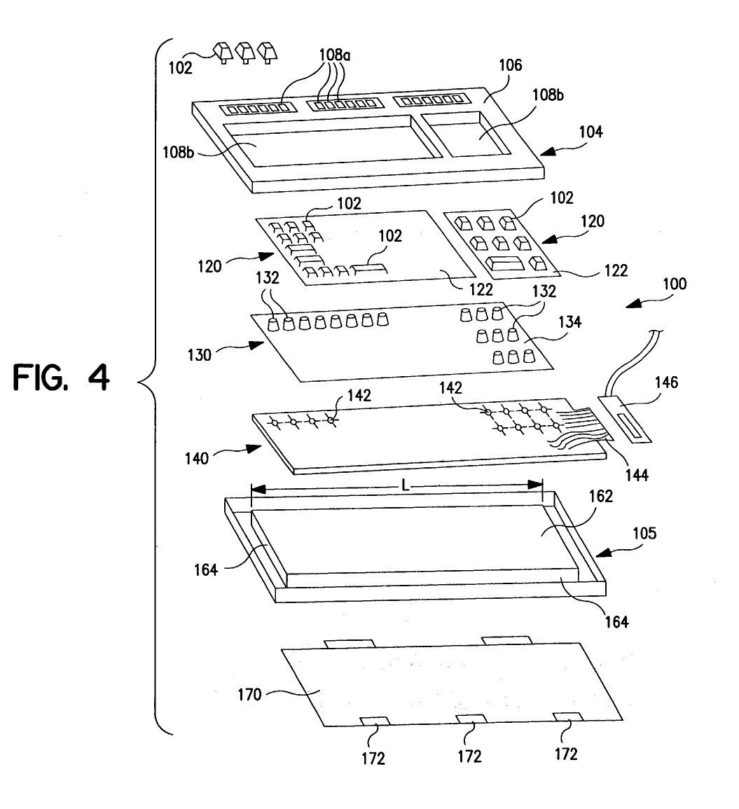

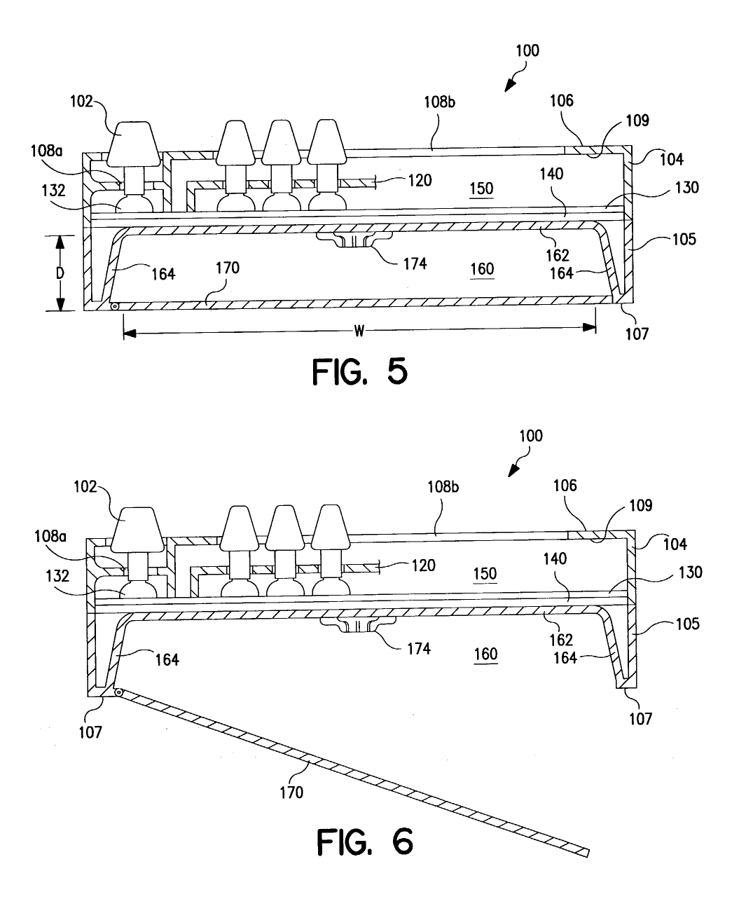

As is illustrated in the exploded view of FIG. 4, the upper portion 104 of the housing 103 includes a plurality of openings 108a, 108b in which the keys 102 are located. In an alternative embodiment, the upper portion 104 has only one opening 108b. The openings 108a, 108b are conduits that pass through the housing 103 and are sized to receive a portion of a single key or are sized to receive multiple keys. For example, as is best illustrated in FIGS. 5 and 6, in the illustrated computer keyboard 100, the upper portion 104 includes a number of openings 108a that each receive the protrusion of a single key 102. When assembling the computer keyboard 100, the retaining clips of each key 102 snap into one of the openings 108a so as to moveably retain the key in the respective opening 108a. In this manner, each opening 108a accommodates movement of one key 102. Hence, FIG. 1 illustrates some of the openings 108a accommodating the respective protrusion of individual keys 102.

The openings 108b (see FIGS. 1, and 4-6) are sized to receive a plurality of keys 102 (at least two). More specifically, each opening 108b receives a modular key assembly 120 having a number of keys 102 thereon. Each modular key assembly 120 includes a base plate 122 having a number of openings therein that are similar to the openings 108a in the upper portion 104 of the housing 103. Each of the openings in the base plate 122 receives the protrusion and retaining clips of a single key 102 so as to moveably retain the received key in the opening of the base plate. Each of the keys 102 is freely moveable in the openings of the base plate 122. That is, the keys 102 are not biased in any direction of movement. The keys 102 in the openings 108b move with respect to the upper portion 104 of the housing 104 in a similar manner as the keys in the openings 108a.

Each modular key assembly, or at least a portion thereof, is inserted into the respective opening 108b of the upper portion 104 of the housing 103. The modular key assembly 120 is retained in the opening 108b by one or more clips, screws, snaps, press fits, ledges, locators or other devices of the modular key assembly and/or the housing 103. Because each modular key assembly 120 is located in an opening 108b, the keys 102 are also located in the opening 108b. In this manner, each opening 108b accommodates movement of a plurality of keys 102.

As is apparent, the keys 102 can be retained to the keyboard 100 in other manners, such as those described in U.S. Pat. Nos.: 3,736,397; 4,362,408; 4,791,257; 4,906,117; and 5,676,476, the entire disclosures of which are hereby incorporated by reference.

In the illustrated embodiment, the computer keyboard 100 also includes a resistance setting device 130, which can be one or more sheet-like items having a plurality of deformable members 132 that protrude from an upper surface 134 thereof. When the resistance setting device 130 is located in the computer keyboard 100, the deformable members 132 resist movement of the keys. That is, one or more of the deformable members 132 is disposed directly adjacent the protrusion (or other intermediary member) of each key 102 such that when a user strikes a key, the deformable member resists movement of the key. When a user strikes the key 102 with sufficient force to overcome the resistance of the deformable member 132, the deformable member will deform; when the user removes the striking force, the deformable member and the adjacent key 102 will return to its static position. The resistance setting device 130 and its deformable members 132 are preferably constructed of an elastomeric material having a suitable durometer or hardness necessary to achieve a desired keystroke resistance. For example, the resistance setting device 130 may be constructed, i.e., molded, cast, stamped, woven, etc., from a polymeric material, such as polyurethane, polypropylene, polyethylene, equivalents of these materials, and blends of these materials. Additionally, the resistance setting device 130 may be constructed of a synthetic or natural rubber. The resistance setting device 130 may also be fabricated from a conductive elastomeric material. In a further embodiment, the resistance setting device 130 is formed from a combination of materials, such as a woven nylon sheet having polyethylene deformable members 132 secured thereto. The resistance setting member 130 may be similar to that described in WO 00/73078 A1 and U.S. Pat. Nos. 5,494,363, 5,588,760 and 5,933,133, the entire disclosures of which are hereby incorporated by reference.

In a preferred embodiment, the resistance setting device 130 is the only device that resists movement of the keys 102. That is, the computer keyboard 100 preferably does not include any other devices besides the deformable members 132 that resist striking movement of the keys 102. However, in alternative embodiments, movement of the keys 102 is resisted by devices in addition to the deformable members 132. For example, movement of the keys 102 may also be resisted by one or springs or pads, such as that described in some the earlier referenced patent publications. In a further embodiment, the computer keyboard 100 does not include the resistance setting device 130. Rather, the resistance of the keys 102 is set by other devices, such as individual metallic springs.

As is also illustrated in FIGS. 4-6, a circuit board 140 is located directly underneath the resistance setting device 130. Hence, the resistance setting device 130 is located between the keys 102 and the circuit board 140. The circuit board 140 is of a conventional construction and has a plurality of switches 142 that are switched, i.e. tripped or closed, when the deformable member contacts the circuit board. When the deformable member 132 contacts the circuit board 140, a signal is sent via the circuits of the circuit board 140.

In one embodiment, the circuit board 140 is a flexible membrane type circuit board, which is widely employed in the keyboards of personal computers, such as those illustrated in U.S. Pat. Nos. 5,434,566 and 5,588,760, the entire disclosures of which are hereby incorporated by reference. A suitable flexible membrane type circuit board includes two flexible films on which electrical contacts are formed in opposed relation with a spacer barrier there between. The spacer barrier includes a number of holes there through that are located at positions corresponding to the contacts of the respective barriers. When a key 102 deforms the deformable member 132, the deformable member will cause the opposed electrical contacts to touch and close the switch.

In a further embodiment, the circuit board 142 is a single barrier type circuit board, and each deformable member has a conductive insert therein or is formed of a conductive material. When the conductive insert or the conductive deformable member contacts the barrier, it creates an electrical contact to switch one of the switches 142. An example of this type of circuit board is described in U.S. Pat. No. 5,494,363, the entire disclosure of which is also hereby incorporated by reference.

As is illustrated in FIG. 4, the switches 142 of the circuit board 140 are connected via conductive lines or patterns to connecting lines of a tongue 144 in the conventional manner. As is known, each switch 142 corresponds to a specific key 102, depending upon each key's respective position. The connecting lines of the tongue 144 are in turn connected to a printed circuit board 146 or equivalent device, which translates the signals from the switches 142 in any one of a variety of conventional manners. The printed circuit board 146 is in turn connected to an electronic cord or wireless connection device that communicates with a computer.

As is illustrated in FIGS. 5 and 6, the computer keyboard 100 includes and interior area 150 in which the keys 102 and deformable members 132 move when a user operates the keyboard. In the illustrated embodiment, the interior area 150 is located between the circuit board 140 and an inside surface 109 of the upper portion 104 of the housing 103. As is also illustrated, the computer keyboard 100 includes a storage area 160, which is at least partially defined by the housing 103. In the illustrated embodiment, the storage area 160 is an area that is separate from the interior area 150 in which the keys 102 move. In the illustrated embodiment, the bottom portion 105 of the housing 103 includes four side walls 164 that slope away from the bottom side 107 of the housing to a recessed wall 162. Hence, the wall 162 is recessed from the bottom side 107 of the housing 103. Hence, the lower portion 105 of the housing 103 defines the storage area 160, which is bounded by the four side walls 164 and the recessed wall 162.

The recessed wall 162 is preferably planar and is recessed from the bottom side 107 a predetermined depth D (as measured along a depth axis that is generally perpendicular to the recessed wall 162 or upper side 106). The predetermined depth D is preferably sufficient to accommodate portable secondary storage devices, such as optical and magnetic disks, cards, tapes, etc., as well as some computer-related documents. In the particular embodiment illustrated in the Figures, the predetermined depth D is approximately 10 mm, such that the storage area 160 is deep enough to accommodate most portable secondary storage devices, as well as some computer related paperwork. In alternative embodiments, the storage area 160 may be configured to accommodate only certain types of portable secondary storage devices. In many configurations, the predetermined depth D is in the range 1-50 mm. In particular embodiments, D is 1-30 mm, 5-20 mm, 10-20 mm, 20-40 mm, 30-50 mm. As is illustrated in FIG. 4, the recessed wall 162 is continuous, i.e., it is devoid of any openings or voids passing there through. However, in an alternative embodiment, the recessed wall 162 may have one or more openings passing there through such that the interior area 150 is in communication with the storage area. For instance, in one embodiment the recessed wall 162 only partially separates the interior area 150 and the storage area 160. In a further embodiment, the recess wall 162 is a perforated so as to define a cage-like wall. The recess wall can also be absent, such as in a configuration where the upper surface of the storage area is defined by the lower surface of a circuit board or by a divider between the circuit board and the storage area (e.g., a metal or plastic plate attached to the bottom of the circuit board and/or to the housing).

As is illustrated in FIGS. 5 and 6, the circuit board 140 abuts the recessed wall 162. Hence, the recessed wall 162 extends a predetermined length L (as measured along a longitudinal axis of the computer keyboard), which in the illustrated embodiment is approximately equal to or greater than the length of the circuit board 140. In the particular embodiment illustrated in the Figures, the predetermined length L is approximately 340 mm, which is also sufficiently long to accommodate most portable secondary storage devices, as well as some computer related paperwork. In an alternative embodiment, the circuit board 140 abuts a metallic plate or other device located between the circuit board and the recessed wall 162. In alternative embodiments, the storage area 160 is configured to accommodate only certain types of portable secondary storage devices, e.g., CDs, DVDs, floppy disks, and solid state memory modules. In many embodiments, the predetermined length L is in the range 20-500 mm, e.g., in a range 50-400 mm, 100-400 mm, 100-300 mm, 200-400 mm, or 200-350 mm.

As is illustrated in FIG. 5, the recessed wall 162 also extends a predetermined width W (as measured along an axis perpendicular to the longitudinal axis of the computer keyboard and generally parallel to the recessed wall 162), which in the illustrated embodiment is approximately equal or greater than the width of the circuit board 140. Hence, in the particular embodiment illustrated in the Figures, the predetermined width W is approximately 130 mm (±20%), which is sufficiently wide to accommodate most portable secondary storage devices, as well as some computer related paperwork. In alternative embodiments, the storage area 160 is configured to accommodate only certain types of portable secondary storage devices. In particular embodiments, the predetermined width W is in a range 20-200 mm, 50-150 mm, 100-150 mm, 100-200 mm, or 80-130 mm.

In one embodiment of the computer keyboard, the Length L of the storage area 160 is between 20-500 mm, the depth D of the storage area is between 1-50 mm, and the width W of the storage area is between 20-200 mm. In another embodiment of the computer keyboard, the Length L of the storage area 160 is between 50-400 mm, the depth D of the storage area is between 1-30 mm, and the width W of the storage area is between 50-150. mm. In a further embodiment of the computer keyboard, the Length L of the storage area 160 is between 200-350 mm, the depth D of the storage area is between 5-20 mm, and the width W of the storage area is between 100-150 mm. Keyboards may also be constructed with other selections of L, D, and W, e.g., in accordance with the various selections indicated above, in any individual combination. Thus, storage areas of varying thickness, width, and length can be constructed as desired, and/or as needed to accommodate particular types of materials for storage and/or to fit length and width dimensions for a particular keyboard layout.

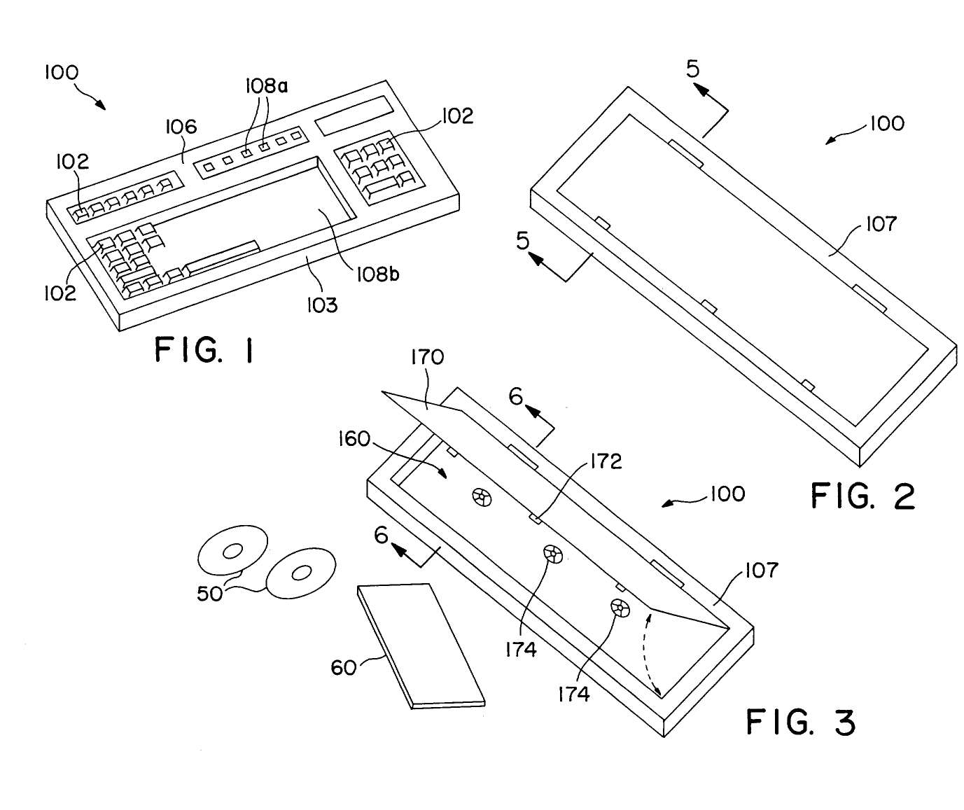

The computer keyboard 100 is constructed such that the storage area 160 is covered by a cover 170 to define a compartment in the computer keyboard that is openable and closeable via the cover such that a user can contain an object within the storage area and remove the object from the storage area. Hence, the cover 170 is moveable from a closed position illustrated in FIGS. 2 and 5 to an open position illustrated in FIGS. 3 and 6. When at the closed position illustrated in FIG. 5, the cover 170 covers the storage are 160 to retain any objects therein. When at the open position illustrated in FIG. 6, the storage area 160 is exposed and accessible by a user such that the user can insert objects into the storage area 160 and remove previously stored objects from the storage area. In the illustrated embodiment, the cover 170 is a rigid, solid, and rectangular wall of plastic material that pivotably attached to the housing 103 via a hinge connection that permits the cover 170 to rotate with respect to the housing 130 about the hinge connection as illustrated in FIG. 3. In alternative embodiments of the computer keyboard 100, the cover 170 is perforated. In further embodiments, the cover 170 is flexible. For example, the cover 170 may be defined by netting or an elastic strap(s) that is removably or hingedly attached to the housing 103 so as to retain objects in the storage area. A cover is not necessary, as materials may be retained in a storage area by other means, or the storage are may be configured such that materials will be held in the storage are by gravity and/or by friction and/or by other retainers such as straps, clips, bands, and the like.

The cover also includes retaining members 172, such as snaps, keys, threaded attachments, clips, buttons, and/or other retainers that retain the cover to the housing 103 to keep the cover in the closed position illustrated in FIG. 2. In the illustrated embodiment, the retaining members 172 are flexible clips. When the user desires access to the storage area 160, the user flexes the retaining members 172 away from the housing and rotates or pivots the cover to the open position illustrated in FIGS. 3 and 6. As will be appreciated, the cover 170 may be retained to the housing 103 in any variety of manners so long as the cover 170 covers the storage area 160 to define a compartment for the storage of objects, such as the portable secondary storage devices 50 and the computer related paperwork 60. Because the storage area 160 is part of the computer keyboard, users of the keyboard have an easily recollected location in which computer readable media and/or paperwork may be stored for future use, such as when a program or operating system needs to be reinstalled on the user's computer.

In the illustrated embodiment, the storage area has a number of conventional disk holding hubs 174 located therein for holding disk type portable secondary storage devices in a fixed location within the storage area 160. As is illustrated in FIG. 3, 5, and 6, the disk holding hubs 174 protrude from the recessed surface 162. In an alternative embodiment, the disk holding hubs protrude from the inside surface of the cover 170 that faces the recessed surface 162 when the cover is closed. Such disk holding hubs can generally be utilized in many different embodiments, including the various embodiments described or illustrated herein, and are not limited to covered storage areas or the embodiments particularly showing disk holding hubs shown in drawings herein.

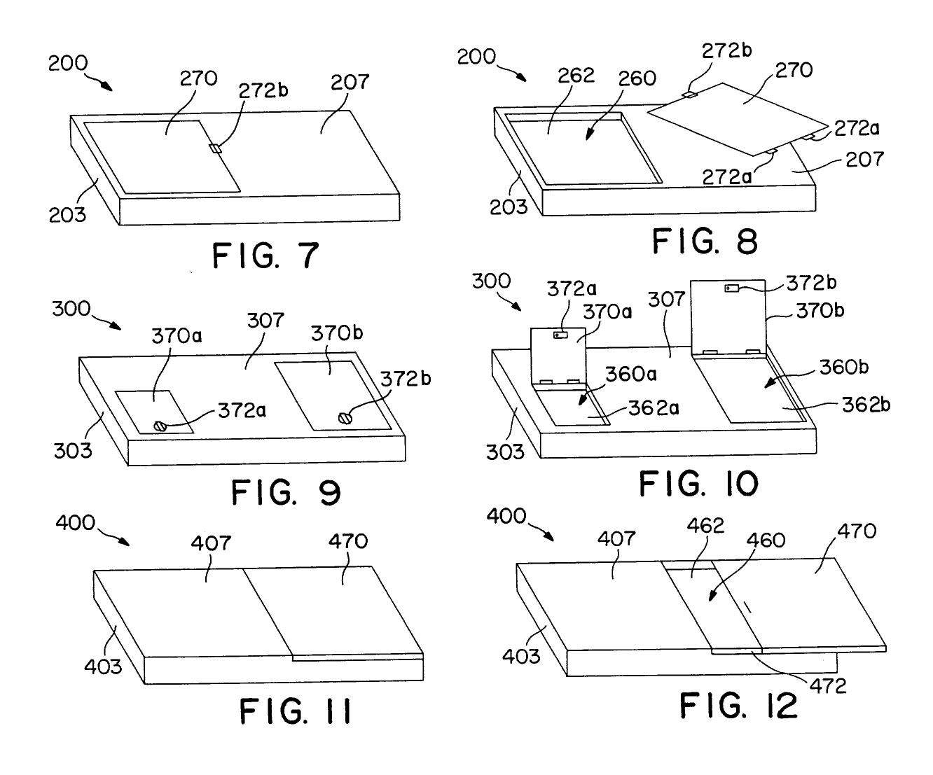

FIGS. 7-19 illustrate additional embodiments of computer keyboards 200, 300, 400, 500, 600, 700 in accordance with the present invention. As described below, the computer keyboards 200, 300, 400, 500, 600, 700 each include a storage area 260, 360, 460, 560, 660, 760 in which a user of the keyboard can store objects, such a computer readable secondary storage devices and computer related paperwork to lessen the chance that the user will misplace such objects. Because the computer keyboards, 200, 300, 400, 500, 600, 700 are functionally similar and share a number of similar parts, in the following description like numbered parts of the computer keyboards 200, 300, 400, 500, 600, 700 are referred to by like numbers as the keyboard 100, increased by 100's and letters (a,b).

Like the computer keyboard 100, the computer keyboard 200 includes a housing 203 having a recessed wall 262 that is recessed from a bottom side 207 of the keyboard (opposite from the upper side where the keys are located). The recessed wall 262 at least partially separates an interior area in which the keys move from the storage area 260. In the illustrated embodiment, the storage area is sized to receive at least a 120 mm diameter disk and has the following dimensions: Length L 180 mm, Width W 150 mm, Depth D 3 mm. The computer keyboard 200 also includes a cover 270 that covers the storage area 260 to define a compartment in the computer keyboard that is openable and closeable such that a user can contain objects within the storage area and remove objects from the storage area. Hence, the cover 270 is moveable from a closed position illustrated in FIG. 7 to an open position illustrated in FIG. 8. When at the closed position, the cover 270 covers the storage area 260 to retain objects therein. When at the open position, the storage area 260 is exposed and accessible by a user such that the user can insert objects into the storage area 260 and remove previously stored objects from the storage area. In the illustrated embodiment, the cover 270 is removeably attached to the housing 203 via a combination of retaining members 272a,b. The retaining members 272a are protrusions while the retaining member 272b is a flexible clip. Together, the retaining members 272a,b retain the cover to the housing 203 to keep the cover in the closed position illustrated in FIG. 7. When the user desires access to the storage area 260, the user flexes the clip 272b away from the housing and lifts the cover away from the housing 103 to an open position, such as illustrated in FIG. 8. Because the storage area 260 is part of the computer keyboard, users of the keyboard have an easily recollected location in which computer readable medium and/or paperwork may be stored for future use.

The computer keyboard 300 includes a housing 303 having recessed walls 362a,b that each are recessed from a bottom side 307 of the keyboard (opposite from the upper side where the keys are located). Each recessed wall 362a,b at least partially separates an interior area in which the keys move from a respective storage area 360a,b. In the illustrated embodiment, the storage area 360a is sized to receive a memory card and has the following dimensions: Length L 60 mm, Width W 100 mm, Depth D 20 mm. The storage area 360a is sized to receive paperwork and/or disks and has the following dimensions: Length L 150 mm, Width W 180 mm, Depth D 20 mm. The computer keyboard 300 also includes cover 370a,b that each covers the respective storage area 360a,b to define compartments in the computer keyboard that each are openable and closeable such that a user can contain objects within the storage areas and remove objects from the storage areas. Hence, the covers 370a,b are moveable from the closed positions illustrated in FIG. 9 to the open positions illustrated in FIG. 10. When at the closed positions, the respective covers 370a,b cover the respective storage areas 360a,b to retain objects therein. When at the open positions, the respective storage areas 360a,b are exposed and accessible by a user such that the user can insert objects into the respective storage areas 360a,b and remove previously stored objects from the respective storage areas. In the illustrated embodiment, the covers 370a,b are pivotably attached to the housing 303 via a hinge connection and are retained to the housing via retaining members 372a,b, which are rotatable locks. Each lock 372a,b retains the respective cover 370a,b to the housing 303 to keep the cover in the closed position illustrated in FIG. 9. When the user desires access to the storage areas 360a,b, the user rotates the locks 371a,b and pivots the covers away from the housing 103 to an open position, such as that illustrated in FIG. 10. Because the storage areas 360a,b are part of the computer keyboard, users of the keyboard have an easily recollected location in which computer readable medium and/or paperwork may be stored for future use.

The computer keyboard 400 includes a housing 403 having a recessed wall 462 that is recessed from a bottom side 407 of the keyboard (opposite from the upper side where the keys are located). The recessed wall 462 at least partially separates an interior area in which the keys move from the storage area 460. In the illustrated embodiment, the storage area 460 has the following dimensions: Length L 340 mm, Width W 130 mm, Depth D 20 mm. The computer keyboard 400 also includes a cover 470 that covers the storage area 460 to define a compartment in the computer keyboard that is openable and closeable such that a user can contain objects within the storage area and remove objects from the storage area. Hence, the cover 470 is moveable from a closed position illustrated in FIG. 11 to an open position illustrated in FIG. 12. When at the closed position, the cover 470 covers the storage area 460 to retain objects therein. When at the open position, the storage area 460 is exposed and accessible by a user such that the user can insert objects into the storage area 460 and remove previously stored objects from the storage area. In the illustrated embodiment, the cover 470 is slideably attached to the housing 403 via a retaining member 472, which is a slide and groove device. When the user desires access to the storage area 460, the user slides the cover from the closed position illustrated in FIG. 11 to the open position illustrated in FIG. 12. Because the storage area 460 is part of the computer keyboard, users of the keyboard have an easily recollected location in which computer readable medium and/or paperwork may be stored for future use.

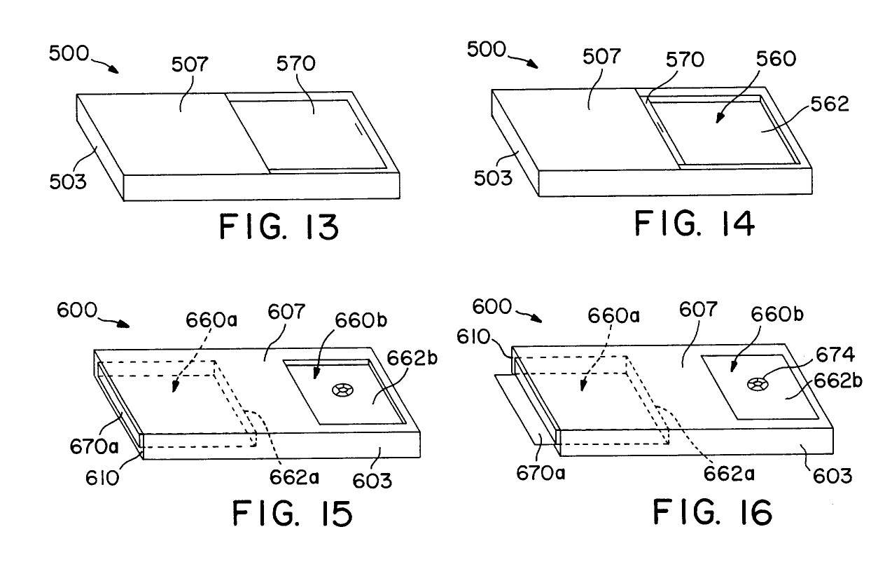

Similar to the computer keyboard 400, the computer keyboard 500 includes a housing 503 having a recessed wall 562 that is recessed from a bottom side 507 of the keyboard (opposite from the upper side where the keys are located). The recessed wall 562 at least partially separates an interior area in which the keys move from the storage area 560. In the illustrated embodiment, the storage area 560 has the following dimensions: Length L 340 mm, Width W 130 mm,. Depth D 20 mm. The computer keyboard 500 also includes a cover 570 that covers the storage area 560 to define a compartment in the computer keyboard that is openable and closeable such that a user can contain objects within the storage area and remove objects from the storage area. Hence, the cover 570 is moveable from a closed position illustrated in FIG. 13 to an open position illustrated in FIG. 14. When at the closed position, the cover 570 covers the storage area 560 to retain objects therein. When at the open position, the storage area 560 is exposed and accessible by a user such that the user can insert objects into the storage are 560 and remove previously stored objects from the storage area. In the illustrated embodiment, the cover 570 is slideably attached to the housing 503 via a retaining member (not illustrated), which is a slide and groove device inside the housing 103. When the user desires access to the storage area 560, the user slides the cover from the closed position illustrated in FIG. 13 into the housing to the open position illustrated in FIG. 14. Because the storage area 560 is part of the computer keyboard, users of the keyboard have an easily recollected location in which computer readable medium and/or paperwork may be stored for future use.

The computer keyboard 600 includes a housing 603 having recessed walls 662a,b. The recessed wall 662b is recessed from a bottom side 607 of the keyboard (opposite from the upper side where the keys are located), while the recessed wall 662a is recessed from a transverse side 610 of the housing that is approximately transverse to the bottom side 607. Each recessed wall 662a,b at least partially separates an interior area in which the keys move from a respective storage area 660a,b. In the illustrated embodiment, the storage area 660a has the following dimensions: Length L 200 mm, Width W 150 mm, Depth D 20 mm. The storage area 660b is sized to receive a compact disk and has the following dimensions: Length L 130 mm, Width W 130 mm, Depth D 5 mm. The computer keyboard 600 also includes a cover 670a that covers the storage area 660a to define a compartment in the computer keyboard that is openable and closeable such that a user can contain objects within the storage area 660a and remove objects from the storage area. Hence, the cover 670a is pivotable from a closed position illustrated in FIG. 15 to an open position illustrated in FIG. 16. When at the closed position, the cover 670a covers the storage area 660a to retain objects therein. When at the open position, the storage area 660a is exposed and accessible by a user such that the user can insert objects into the storage area 660a and remove previously stored objects from the storage area. In the illustrated embodiment, the cover 670a is pivotably attached to the housing 603 via a hinge connection and is retained to the housing via retaining members (not illustrated). When the user desires access to the storage area 660a, the user rotates the cover 670 away from the side 609 of the housing 103 to an open position illustrated in FIG. 16. Because the storage area 660a is part of the computer keyboard, users of the keyboard have an easily recollected location in which computer readable medium and/or paperwork may be stored for future use. As is illustrated in FIGS. 15 and 16, the storage area 660b does not include a cover. Rather the storage area is open or exposed for immediate access and includes a disk holding hub 674 that holds one or more disk-type portable secondary storage devices in a fixed location within the storage area 660b. The disk holding hub 674 protrudes from the recessed surface 662. To use the disk holding hub, a user will attached a disk to the hub such that the storage area 660b stores the disk therein.

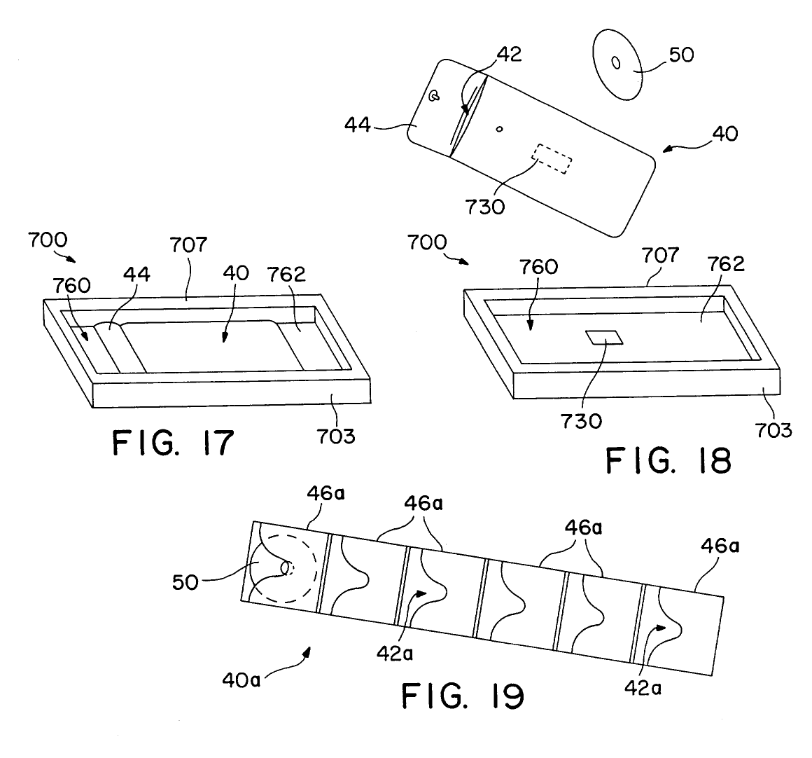

The computer keyboard 700 includes a housing 703 having a recessed wall 762. The recessed wall 762 is recessed from a bottom side 707 of the keyboard (opposite from the upper side where the keys are located). The recessed wall 762 at least partially separates an interior area in which the keys move from a storage area 760. The storage area 760 is sized to receive a receptacle 40, which is a flexible or stiff container that holds objects, such as the computer readable medium 50 and computer related documents. In the illustrated embodiment, the receptacle 40 is a flexible folder having a pocket 42 that is sized to receive at least a computer readable medium 50. The pocket 42 is openable and closeable by a flap 44. As is illustrated in FIG. 18, the receptacle 40 is releaseably coupled to the recessed wall 762 by a coupling mechanism 730 such that the receptacle may be repeatedly attached to and unattached from the keyboard 700. The coupling mechanism 730 is a hook and loop mechanism, but may be other coupling mechanisms, such as a lock and key mechanism, a fastener, a clip, a button, a snap, or other known coupling mechanism. A user of the computer keyboard 700 can contain objects within the storage area 760 and remove objects from the storage area via the receptacle 40. Hence, a user can store an object in the pocket 42 of the receptacle 40 and then attach the receptacle to the wall 762 via the coupling 730 such that the receptacle 40 (and any objects stored therein) are stored in the storage area 760. FIG. 17 illustrates the receptacle 40 attached to the computer keyboard and located within the storage area 760, while FIG. 18 illustrates the receptacle 40 removed from the storage area 760. Thus, a user can insert objects into the storage area 760 and remove previously stored objects from the storage area. FIG. 19 illustrates an alternative embodiment of a receptacle 40a for use with the computer keyboard 700. The receptacle 40a includes a number of foldable segments 46a each having a pockets 42 in the form of a sleeve sized to receive a disk-type computer readable medium 50. Like the receptacle 40, the receptacle 40a includes a coupling mechanism (not illustrated) such that the receptacle may be repeatedly attached and unattached from the interior of the storage area 760 of the keyboard 700. In an alternative embodiment of the computer keyboard 700, the receptacle 40 is permanently attached within the storage area 760, such as by an adhesive or interference fit attachment.

Rather than having a cover that can be slid, swung away, or removed to access a storage area, a storage container or receptacle can itself be slidable, hinged or removable. For example, the storage container or receptacle can be a bin-shaped container (or a box-shaped container, a rectangular pocket-shaped container, or a slidable tray that fits in a slot or pocket). A bin-shaped container can be slidably attached with the opening upward (thus forming a drawer), removable (with the open part of the bin up when the bin is attached to the keyboard in normal position), or hinged, e.g., with the hinge side toward the back of the keyboard. Likewise, a tray can slide out of a horizontally arranged slot or pocket to expose one or more storage locations, e.g., one or more disk holding hubs, sleeves, or retaining straps. Such trays will generally slide out on a side, e.g., lateral or front side.

In yet another configuration, a storage care can include one or more brackets, straps or bands to retain stored materials, either directly or in storage receptacles. Thus, for example, disks can be placed in a cassette or other disk storage device that is retained in a bracket, e.g., a T-shaped bracket that retains the cassette on 3 sides. The cassette or other device can be held in various ways, e.g., by friction against the bracket or by using a retainer over an open side of a bracket, such as a rigid or flexible strap, band, or latch.

All patents and other references cited in the specification are indicative of the level of skill of those skilled in the art to which the invention pertains, and are incorporated by reference in their entireties, including any tables and figures, to the same extent as if each reference had been incorporated by reference in its entirety individually.

One skilled in the art would readily appreciate that the present invention is well adapted to obtain the ends and advantages mentioned, as well as those inherent therein. The methods, variances, and compositions described herein as presently representative of preferred embodiments are exemplary and are not intended as limitations on the scope of the invention. Changes therein and other uses will occur to those skilled in the art, which are encompassed within the spirit of the invention, are defined by the scope of the claims.

It will be readily apparent to one skilled in the art that varying substitutions and modifications may be made to the invention disclosed herein without departing from the scope and spirit of the invention. For example, other materials may be used to construct keyboards and storage areas. Thus, such additional embodiments are within the scope of the present invention and the following claims.

The invention illustratively described herein suitably may be practiced in the absence of any element or elements, limitation or limitations which is not specifically disclosed herein. Thus, for example, in each instance herein any of the terms “comprising”, “consisting essentially of” and “consisting of” may be replaced with either of the other two terms. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

In addition, where features or aspects of the invention are described in terms of Markush groups or other grouping of alternatives, those skilled in the art will recognize that the invention is also thereby described in terms of any individual member or subgroup of members of the Markush group or other group.

Also, unless indicated to the contrary, where various numerical values are provided for embodiments, additional embodiments are described by taking any 2 different values as the endpoints of a range. Such ranges are also within the scope of the described invention.

Thus, additional embodiments are within the scope of the invention and within the following claims.

What is claimed is:

1. A computer keyboard for use with a computer that is separate from said computer keyboard, said computer keyboard comprising:
an upper side, a lower side, and a transverse side, wherein a plurality of keys are located at said upper side, and said lower side comprises an externally accessible storage area.

2. The computer keyboard of claim 1, wherein said housing has an interior area in which said plurality of keys are moveable when a user actuates said keys, and said storage area is separated from said interior area by a wall of said housing and is covered by a cover that is openable and closeable such that the user can contain an object within said storage area and remove the object from said storage area.

3. The computer keyboard of claim 2, said wall being recessed from said another side, said another side being a bottom side of said housing located opposite from said upper side of said housing.

4. The computer keyboard of claim 2, said wall being recessed from said another side, said another side being a side of said housing that is transverse to said upper side of said housing.

5. The computer keyboard of claim 2, said cover being pivotally attached to said housing.

6. The computer keyboard of claim 2, said cover being slidably attached to said housing.

7. The computer keyboard of claim 2, said cover being removably attached to said housing.

8. The computer keyboard of claim 2, said cover including at least one retaining member for retaining said cover to said housing.

9. The computer keyboard of claim 1, said storage area including a disk holding hub.

10. The computer keyboard of claim 1, wherein said storage area has dimensions: length L 20-500 mm; width W 20-200 mm; and depth D 1-50 mm.

11. The computer keyboard of claim 1, wherein said storage area has dimensions: length L 50-400 mm, width W 50-150 mm, and depth D 1-30 mm.

12. The computer keyboard of claim 2, further comprising:
a device having a plurality of deformable members for setting a resistance of said keys, said device having said plurality of deformable members being within said interior area.

13. The computer keyboard of claim 1, said storage area being a first storage area, further comprising a second storage area.

14. The computer keyboard of claim 1, said storage area being sized to store a computer readable secondary storage device.

15. The computer keyboard of claim 14, said computer readable secondary storage device being a disk having a diameter of at least 40 mm.

16. The computer keyboard of claim 2, said housing having an upper portion and a lower portion, said lower portion having said wall.

17. The computer keyboard of claim 1, further comprising a housing, wherein said storage area comprises a volume defined by transverse walls of said housing.

18. The computer keyboard of claim 17, further comprising a cover over said volume.

19. The computer keyboard of claim 17, wherein the lesser of the length L and width W of said volume is at least 100 mm.

20. The computer keyboard of claim 19, wherein said volume is at least 200 cm³.

21. The computer keyboard of claim 1, wherein said keyboard comprises at least two legs at said lower side, wherein said legs elevate said keyboard thereby creating a volume for said storage area.

22. The computer keyboard of claim 1, wherein said storage area comprises a slidable drawer.

23. The computer keyboard of claim 1, wherein said storage area comprises a strap or band for retaining materials stored in said storage area.

24. The computer keyboard of claim 1, wherein said storage area comprises a removable bin.

25. The computer keyboard of claim 1, wherein said storage area comprises a hub for holding a disk at said lower side.

26. The computer keyboard of claim 25, further comprising a cover for covering said storage area.

27. The computer keyboard of claim 26, said hub extending from a surface of said cover.

28. The computer keyboard of claim 26, said cover being moveably attached to said housing.

29. The computer keyboard of claim 26, said storage area being at least partially defined by a recessed surface of a housing of said computer keyboard, said recessed surface being recessed from an exterior surface of said computer keyboard.

30. The computer keyboard of claim 29, said hub protruding from said recessed surface.

31. The computer keyboard of claim 1, further comprising at least one secondary storage media item stored in said storage area.

32. The computer keyboard of claim 31, wherein said secondary storage media item is selected from the group consisting of compact disk, digital versatile disk, and floppy disk.

33. A computer keyboard for use with a computer that is separate from said computer keyboard, said computer keyboard comprising:
a plurality of keys located at an upper side of a housing of said keyboard, said housing having an interior area in which said plurality of keys are moveable when a user actuates said keys, said housing also having a storage area at another side of said keyboard, said storage area being separated from said interior area by a wall of said housing, said storage area including therein a separate storage receptacle for storing an object.

34. The computer keyboard of claim 33, said receptacle being releasably coupled to a surface of said storage area.

35. The computer keyboard of claim 33, wherein said receptacle is slidably attached to a surface of said storage area.

36. The computer keyboard of claim 33, wherein said storage receptacle comprises at least one disk pocket.

37. The computer keyboard of claim 33, wherein said storage receptacle comprises a removable bin.

38. The computer keyboard of claim 33, further comprising at least one secondary storage media item stored in said storage area.

39. The computer keyboard of claim 38, wherein said secondary storage media item is selected from the group consisting of compact disk, digital versatile disk, and floppy disk.

40. A computer system comprising a computer case comprising at least one central processing unit, and a computer keyboard comprising an upper side, a lower side, and a storage area at said lower side.

41. The system of claim 40, further comprising at least one secondary storage media item stored in said storage area.

42. The system of claim 41, wherein said secondary storage media item is selected from the group consisting of compact disk, digital versatile disk, and floppy disk.

43. A method for storing secondary storage media with a computer, comprising storing one or more secondary storage media items in a storage area in a computer keyboard functionally part of said computer.

44. The method of claim 43, wherein said secondary storage media item is selected from the group consisting of compact disk, digital versatile disk, and floppy disk.
